(19) United States
(12) Patent Application Publication
(10) Pub. No.: US 2024/0222190 A1
(43) Pub. Date: Jul. 4, 2024

(54) METHODS FOR FORMING GAP-FILLING MATERIALS AND RELATED APPARATUS AND STRUCTURES

(71) Applicant: ASM IP Holding B.V., Almere (NL)

(72) Inventors: Timothee Blanquart, Oud-Heverlee (BE); Jihee Jeon, Tempe, AZ (US)

(21) Appl. No.: 18/398,796

(22) Filed: Dec. 28, 2023

Related U.S. Application Data
(60) Provisional application No. 63/478,008, filed on Dec. 30, 2022.

(51) Int. Cl. H01L 21/768; C23C 16/40; C23C 16/455; C23C 16/505; C23C 16/52; C23C 16/56; H01J 37/32; H01L 21/02

(52) U.S. Cl. CPC H01L 21/76837; C23C 16/402; C23C 16/45538; C23C 16/45544; C23C 16/505; C23C 16/52; C23C 16/56; H01J 37/32449; H01L 21/02164; H01L 21/02211; H01L 21/02274; H01L 21/0228; H01J 2237/3321

(57) ABSTRACT

Methods and apparatus for forming a structure comprising a substrate. The substrate comprises plurality of recesses. The recesses are at least partially filled with a gap-filling material. The gap-filling material includes silicon.

### CROSS-REFERENCE TO RELATED APPLICATION(S)

This application claims the benefit of U.S. Provisional Application 63/478,008 filed on Dec. 30, 2022, the entire contents of which are incorporated herein by reference.

### FIELD OF INVENTION

The present disclosure generally relates to methods and apparatus suitable for forming electronic devices. More particularly, the disclosure relates to methods for forming gap-filling materials in gap features, such as, trenches, and the like, by plasma-assisted deposition methods. The disclosure further relates to structures including gap-filling materials as well as apparatus for forming such gap-filling materials.

### BACKGROUND OF THE DISCLOSURE

The scaling of semiconductor devices has led to significant improvements in speed and density of integrated circuits. However, with miniaturization of wiring pitch of large-scale integration devices, void-free filling of high aspect ratio trenches (e.g., trenches having an aspect ratio of three or higher) becomes increasingly difficult due to limitations of existing deposition processes. Therefore, there remains a need for processes that efficiently fill high aspect ratio features, e.g., gaps, such as, trenches on semiconductor substrates.

Any discussion, including discussion of problems and solutions, set forth in this section has been included in this disclosure solely for the purpose of providing a context for the present disclosure. Such discussion should not be taken as an admission that any or all of the invention was previously known or otherwise constitutes prior ar.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In particular, the present disclosure describes methods for forming gap-filling materials within gap features, the methods comprising, placing a substrate including a gap feature into a reaction chamber, introducing an oxygen-free halogenated silicon precursor into the reaction chamber, introducing an oxygen-free co-reactant comprising a noble gas into the reaction chamber, and generating a plasma within the reaction chamber, whereby the oxygen-free halogenated silicon precursor and the oxygen-free co-reactant react in the presence of the plasma to form a silicon containing gap-filing fluid that at least partially fills the gap feature. The methods of the present disclosure also include, contacting the substrate with the silicon containing gap-filling fluid thereon with an oxidizing agent, thereby oxidizing the silicon containing gap-filling fluid and in doing so forming a silicon oxide gap-filling material within the gap feature.

In some embodiment, the oxygen-free halogenated silicon precursor is selected from the group consisting of halosilanes of formula SiₙH₂ₙ₊₂₋ₘXₘ, wherein X is a halogen, n is from at least 1 to at most 4, and m is from at least 1 to at most 2n+2.

In some embodiment, the halosilane is selected from the group consisting of Si₂Cl₆, SiCl₂H₂, SiCl₅H, SiCl₄, SiHCl3, Si₃H₈, Si₂Cl₃H₃, SiI₂H₂, SiI₄, SiI₃H, and Si₂₁₄H₂.

In some embodiment, the methods of the present disclosure can also include, heating the silicon oxide gap-filling material in a nonoxidative atmosphere to a temperature between 200° C. and 1100° ° C. thereby increasing the density of the silicon oxide gap-filling material and reducing the WERR of the silicon oxide gap-filling material.

In some embodiment, the silicon oxide gap-filling material comprises a silicon dioxide gap-filling material.

In some embodiment, the silicon dioxide gap-filling material comprises a bulk stoichiometric silicon dioxide (SiO₂) gap-filling material as determined by x-ray photoelectron spectroscopy.

In some embodiment, forming the gap-filling material further comprises, performing multiple cycles of a cyclical process in which a unit cycle comprises, introducing the oxygen-free halogenated silicon precursor and the oxygen-free co-reactant into the reaction chamber, generating the plasma within the reaction chamber, wherein the oxidizing agent is introduced into the reaction chamber in one or more of the unit cycles.

In some embodiment, forming the gap-filling material further comprises, removing the substrate from the reaction chamber, and subsequently contacting the substrate with the oxidizing agent by placing the substrate in an ex-situ oxygen containing atmosphere.

The present disclosure also describes methods for at least partially filling a gap feature with a gap-filling material, the method comprising, placing a substrate including a gap feature into a reaction chamber, introducing a precursor and co-reactant into the reaction chamber, wherein the precursor and the co-reactant have chemical formulae which do contain oxygen (O), nitrogen (N), and carbon (C), generating a plasma within the reaction chamber, whereby the precursor and the co-reactant react in the presence of the plasma to form an oxygen-free gap-filing fluid that at least partially fills the gap feature. The methods of the present disclosure also include, exposing the substrate with the oxygen free gap-filling fluid thereon to an oxidizing agent thereby oxidizing the oxygen free gap-filling fluid and in doing so forming a bulk oxide gap-filling material within the gap feature.

In some embodiment, the precursor is selected from the group consisting of halosilanes of formula SiₙH₂ₙ₊₂₋ₘXₘ, wherein X is a halogen, n is from at least 1 to at most 4, and m is from at least 1 to at most 2n+2.

In some embodiment, forming the gap-filling material further comprises, performing multiple cycles of a cyclical process in which a unit cycle comprises, introducing the precursor and co-reactant into the reaction chamber, generating the plasma within the reaction chamber, wherein the oxidizing agent is introduced into the reaction chamber in one or more of the unit cycles.

In some embodiment, forming a gap-filling material further comprises, removing the substrate from the reaction chamber, and subsequently contacting the substrate with the oxidizing agent by placing the substrate in an ex-situ oxygen containing atmosphere comprising at least one of, a room temperature oxygen atmosphere, or a room temperature ambient air atmosphere.

In some embodiment, the bulk oxide gap-filling material comprises a bulk stoichiometric silicon dioxide (SiO₂) gap-filling material as determined by x-ray photoelectron spectroscopy.

In some embodiment, the oxygen free gap-filling fluid comprises an inorganic polysilane.

In some embodiment, the methods of the present disclosure also include, performing a post-deposition thermal annealing process on the silicon oxide gap-filling material, the annealing process comprising, heating the silicon oxide gap-filling material to a temperature between 200° C. and 1100° C. in a nonoxidative atmosphere comprising, argon (Ar), helium (He), hydrogen (H2), nitrogen (N2), or combinations thereof.

In some embodiment, the silicon oxide gap-filling material has a post thermal anneal average refractive index greater than 1.44 and a WERR less than 12.

Further embodiments of the present disclosure also include apparatus for forming gap-filling materials, the apparatus comprising, a reaction chamber, a radio frequency power source, a gas injection system, a precursor gas source, a co-reactant gas source, an exhaust, and a controller. The reaction chamber comprises a substrate support and an upper electrode. The substrate support comprises a lower electrode. The radio frequency power source is arranged for generating a radio frequency power waveform. The gas injection system is fluidly coupled to the reaction chamber. The precursor gas source is arranged for introducing a silicon precursor and optionally a carrier gas in the reaction chamber. The co-reactant gas source is also arranged for introducing a co-reactant in the reaction chamber. The controller is arranged for causing the system to carry out a method as described herein.

The embodiments of the present disclosure also include semiconductor structures comprising, silicon oxide gap-filling materials formed according to the methods disclosed herein. In addition, the present disclosure also describes semiconductor structures including, a bulk stoichiometric silicon dioxide (SiO₂) gap-filling material at least partially filling a gap feature formed according to methods disclosure herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

While the specification concludes with claims particularly pointing out and distinctly claiming what are regarded as embodiments of the invention, the advantages of embodiments of the disclosure may be more readily ascertained from the description of certain examples of the embodiments of the disclosure when read in conjunction with the accompanying drawings, in which:

FIG. 1 illustrates a simplified schematic representation of a plasma-enhanced atomic layer deposition (PEALD) apparatus suitable for depositing a structure and/or for performing a method in accordance with at least one embodiment of the present disclosure.

FIG. 2 illustrates an exemplary method for forming a gap-filling fluid in accordance with at least one embodiment of the present disclosure.

FIG. 3 illustrates an exemplary method for forming a gap-filling material in accordance with at least one embodiment of the present disclosure; and.

FIG. 4 illustrates a further exemplary method for forming a gap-filling material in accordance with at least one embodiment of the present disclosure;

FIG. 5. illustrates an exemplary method for thermally annealing the gap-filling material post deposition; and

FIG. 6 demonstrates a cross-sectional scanning tunneling electron microscope (STEM) image of an exemplary structure including gap-filling materials at least partially filing multiple gap features in a substrate, the exemplary gap-filling materials formed in accordance with at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “gas” can include material that is a gas at normal temperature and pressure (NTP), a vaporized solid and/or a vaporized fluid, and can be constituted by a single gas or a mixture of gases, depending on the context. A gas other than the process gas, i.e., a gas introduced without passing through a gas distribution assembly, a multi-port injection system, other gas distribution device, or the like, can be used for, e.g., sealing the reaction space, and can include a seal gas, such as a rare gas. The terms “rare gas” and “noble gas” as used herein may be used interchangeably. In some cases, the term “precursor” can refer to a compound that participates in the chemical reaction that produces another compound, and particularly to a compound that constitutes a film matrix or a main skeleton of a film; the term “reactant” may be used interchangeably with the term precursor.

As used herein, the term “co-reactant” can refer to a gas or gases which can react and/or interact with a precursor in order to form a flowable gap fill layer as described herein. The co-reactant may activate precursor oligomerization. The co-reactant may be a catalyst. The co-reactant does not necessarily have to be incorporated in the gap-filling fluid which is formed, though the co-reactant does interact with the precursor during formation of the gap-filling fluid. In other words, in some embodiments the co-reactant is incorporated in the gap-filling fluid whereas in other embodiments, the co-reactant is not incorporated into the gap-filling fluid. Possible reactants include noble gases, which can be brought in an excited state, in particular an excited state such as ion and/or radical induced by means of a plasma, such as He and Ar, as well as other gases such as H₂. Alternative expressions for the term “co-reactant” as used herein may include “reactant”, “gas mixture”, “one or more further gases”, and “gas mixture comprising one or more further gases”.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. This notwithstanding, the chemical compound, substance, or composition of matter may, in some embodiments, comprise other components as trace elements or impurities, apart from the components that are listed.

As used herein, the term “gap-filling fluid”, can also be referred to as “flowable gap fill”, and may refer to an oligomer which is fluid under the conditions under which it is deposited on a substrate and which has the capability to cross link and form a solid film.

As used herein, the term “seam” may refer to a void line or one or more separated voids formed by the abutment of edges formed in a gap-fill metal. The presence of a “seam” can be confirmed using high magnification microscopy methods, such as, for example, scanning transmission electron microscopy (STEM), and transmission electron microscopy (TEM), wherein if observations reveals a clear vertical void line or one or more vertical voids in a recessed feature filled with a gap-fill metal then a “seam” is deemed to be present.

It shall be understood that terms like “depositing” and the like as used herein can refer to a phase change from the gas phase to a solid phase change, through an intermediate flowable phase. Indeed, the meaning of the term “depositing” can include phase changes from a gaseous phase to a fluid phase, and can include processes in which gaseous reactants form fluid, fluid-like, or solidifying fluids. Thus, the meaning of the term “depositing” can encompass similar terms like condensing or forming.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In this disclosure, a gap-feature or recess between adjacent protruding structures and any other recess pattern may be referred to as a “trench.” That is, a trench may refer to any recess pattern including a hole/via. A trench can have, in some embodiments, a width of about 5 nm to about 150 nm, or about 30 nm to about 50 nm, or about 5 nm to about 10 nm, or about 10 nm to about 20 nm, or about 20 nm to about 30 nm, or about 50 nm to about 100 nm, or about 100 nm to about 150 nm. When a trench has a length that is substantially the same as its width, it can be referred to as a hole or a via. Holes or vias typically have a width of about 20 nm to about 100 nm. In some embodiments, a trench has a depth of about 30 nm to about 100 nm, and typically of about 40 nm to about 60 nm. In some embodiments, a trench can have an aspect ratio of about 2 to about 10, and typically of about 2 to about 5. The dimensions of a trench may vary depending on process conditions, film composition, intended application, etc.

When specific process conditions are provided in this disclosure, they are provided for a reaction chamber volume of 1 liter and for 300 mm wafers. The skilled person understands that these values can be readily extended to other reaction chamber volumes and wafer sizes.

Described herein are methods for at least partially filling, or filling, a gap feature by means of a gap-filling material comprising a silicon oxide. A gap feature in a substrate may refer to a patterned recess or trench in a substrate. In addition, a gap feature can refer to an opening or cavity disposed between opposing sidewalls or protrusions extending vertically from the surface of a substrate, or opposing inclined sidewalls of an indentation extending vertically into the surface of a substrate.

Also provided are gap-filling materials produced by the methods of the present disclosure, as well as films resulting from such methods, and structures including such films. The gap-filling materials can be used during manufacturing processes of various semiconductor devices including, but not limited to, cell isolation in 3D cross point memory devices, self-aligned via, dummy gate, reverse tone patterning, PC RAM isolation, cut hard mask, and DRAM storage node contact (SNC) isolation. In particular embodiments, the gap-filling materials of the present disclosure can comprise silicon oxide gap-filling materials which may be employed in a number of process and device applications, such as, for example, as sacrificial layers, and/or silicon oxide plug structures.

In particular, the presently disclosure describes methods comprising, introducing a substrate in a reaction chamber. The substrate can include one or more gap features. The methods can further comprise, forming a gap-filling fluid that at least partially fills the gap feature. In some embodiment, methods for forming the gap-filling fluid can comprise, continuously providing a silicon precursor into a reaction chamber. In some further embodiments, forming the gap-filling fluid can comprise, continuously providing a co-reactant into a reaction chamber. Additionally, in some embodiment, methods for forming the gap-filling fluid can comprise, continuously generating a plasma within the reaction chamber. This notwithstanding, and in some embodiments, at least one of providing a silicon precursor to the reaction chamber and generating a plasma in the reaction chamber can occur intermittently, i.e. in pulses. In some embodiments, the co-reactant can be continuously provided into the reaction chamber, whereas providing the silicon precursor into the reaction chamber and generating a plasma within the reaction chamber can be performed utilizing alternating cycles. In some embodiments, the methods of the present disclosure further include, oxidizing the gap-filling fluids to thereby form oxide gap-filling materials.

In some embodiments, the exemplar methods of the present disclosure include, entirely filling a gap feature with a gap-filling fluid. In some embodiments, the methods of the present disclosure include, filling a gap feature with a gap-filling material without the formation of voids or seams. In other words, in some embodiments, the exemplary deposition methods according to the present disclosure are continued until the gap feature is fully filled with a material having a filling capability, and substantially no voids or seams are formed in the filled gap feature. The presence of voids or seams can be observed by studying the formed gap-filling material by high magnification microscopy methods, such as, for example, scanning tunneling electron microscope (STEM).

In some embodiments, the gap feature can have a depth of at least 5 nanometers (nm) to at most 500 nm, or of at least 10 nm to at most 250 nm, or from at least 20 nm to at most 200 nm, or from at least 50 nm to at most 150 nm, or from at least 100 nm to at most 150 nm.

In some embodiments, the gap feature can have a width of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap feature can have a length of at least 10 nm to at most 10 000 nm, or of at least 20 nm to at most 5 000 nm, or from at least 40 nm to at most 2 500 nm, or from at least 80 nm to at most 1000 nm, or from at least 100 nm to at most 500 nm, or from at least 150 nm to at most 400 nm, or from at least 200 nm to at most 300 nm.

In some embodiments, the gap-filling fluid can extend into a particular gap feature for a distance that equals from at least 1.0 to at most 10.0 times the width of the gap feature. In some embodiments, the gap-filling fluid can extend into a particular gap feature for a distance that equals from at least 1.5 to at most 9.0 times the width of the gap feature. In some embodiments, the gap-filling fluid can extend into a particular gap feature for a distance that equals from at least 2.0 to at most 8.0 times the width of the gap feature. In some embodiments, the gap-filling fluid can extend into a particular gap feature for a distance that equals from at least 3.0 to at most 6.0 times the width of the gap feature. In some embodiments, the gap-filling fluid can extend into a particular gap feature for a distance that equals from at least 4.0 to at most 6.0 times the width of the gap feature. In some embodiments, the gap-filling fluid can extend into a particular gap feature for a distance that equals about 5.0 times the width of the gap feature. In other words, and in some embodiments, the gap-filling fluid fills the gap feature up to any one of the aforementioned distances from the bottom of the gap feature.

In some embodiments, forming the gap-filling fluid comprises, introducing a precursor into the reaction chamber; generating a plasma within the reaction chamber, and introducing a co-reactant into the reaction chamber. In some embodiments, a halosilane silicon precursor and a noble gas co-reactant react in the presence of the plasma to form a gap-filling fluid that at least partially fills the gap feature. It shall be understood that in such embodiments, the resulting gap-filling fluid comprises at least silicon and hydrogen. Subsequent methods of the present disclosure can further oxidize the gap-filling fluid resulting in a silicon oxide gap-filling material.

In some embodiments, the silicon precursor is continuously provided to the reaction chamber. In some embodiments, the silicon precursor is continuously provided to the reaction chamber and at least one of generating the plasma in the reaction chamber and providing the co-reactant to the reaction chamber is done intermittently.

In some embodiments, one or more co-reactants are continuously provided into the reaction chamber. In some embodiments, the one or more co-reactants are continuously provided to the reaction chamber and at least one of, generating the plasma in the reaction chamber, and providing the precursor to the reaction chamber can be done intermittently.

In some embodiments, the plasma can be continuously generated within the reaction chamber. In some embodiments, the plasma can be continuously generated within the reaction chamber and at least one of, providing the precursor to the reaction chamber, and providing the co-reactant to the reaction chamber can be done intermittently.

In some embodiments, no gases other than the silicon precursor and the co-reactant(s) are introduced into the reaction chamber while forming the gap-filling fluid.

In some embodiments, the methods of present disclosure can comprise providing the precursor intermittently to the reaction chamber, and continuously applying a plasma. Thus, in some embodiments, a continuous plasma can be used instead of plasma pulses. In some embodiments, the present methods can involve providing the precursor intermittently to the reaction chamber, and intermittently applying a plasma. Thus, in some embodiments, a silicon precursor can be continuously provided to the reaction chamber whereas a plasma can be generated intermittently.

In some embodiments, the methods of the present disclosure can comprise, continuously providing a precursor and a co-reactant to the reaction chamber, and continuously generating a plasma in the reaction chamber, e.g. through application of RF power, while forming the gap-filling fluid.

In some embodiments, forming the gap-filling fluid comprises, executing a cyclical deposition process. The cyclical deposition process comprises executing a plurality of deposition cycles. A deposition cycle can comprise, a precursor pulse, and a plasma pulse. The precursor pulse can comprise, introducing a silicon precursor into the reaction chamber. The plasma pulse can comprise, generating a plasma within the reaction chamber and introducing a co-reactant into the reaction chamber. In some embodiments, the plasma pulse can comprise a step in which the plasma can be generated while the co-reactant is being introduced in the reaction chamber. Additionally or alternatively, the plasma pulse can comprise a co-reactant introduction step followed by a plasma strike step. During the co-reactant introduction step, the co-reactant can be provided to the reaction chamber. During the plasma strike step, a plasma can be generated within the reaction chamber. Thus, in some embodiments, the precursor and the co-reactant are allowed to react in the presence of the plasma to form a gap-filling fluid that fills the gap feature at least to some extent. The gap-filling fluid can comprise, silicon, and hydrogen. If desired, the deposition cycle can be repeated one or more times until a suitable amount of gap-filling fluid has been deposited in the gap feature. Subsequently the gap-filling fluid can be oxidized to form a silicon oxide gap-filling material.

In some embodiments, the gap feature can be entirely filled with the gap-filling fluid. It should be understood that the gap-filling fluid can be described as a viscous material, i.e. a viscous phase that is deposited on the substrate. The gap-filling fluid is capable of flowing in a trench on the substrate. Suitable substrates can include, but are not limited to, silicon wafers, for example. As a result, the viscous material seamlessly fills the gap feature, such as a vertical trench, in a bottom-up way.

In some embodiments, the method for filling a gap feature can comprise, from at least 10 to at most 30000 deposition cycles, or from at least 10 to at most 3000 deposition cycles, or from at least 10 to at most 1000 deposition cycles, or from at least 10 to at most 500 deposition cycles, or from at least 20 to at most 200 deposition cycles, or from at least 50 to at most 150 deposition cycles, or from at least 75 to at most 125 deposition cycles, for example 100 deposition cycles.

In some embodiments, the precursor pulse and the plasma pulse can at least partially overlap. In other words, the precursor pulse and the plasma pulse occur at least partially simultaneously. In such embodiments, the cyclical deposition process does not contain an intra-cycle purge. In some embodiments, the cyclical deposition process does not contain an inter-cycle purge.

In some embodiments, no gases other than the silicon precursor, the noble gas, and H are introduced into the reaction chamber during the silicon precursor pulse and during the plasma pulse. Additionally or alternatively, and in some embodiments, no gases other than the noble gas or H are introduced into the reaction chamber during at least one of the intra-cycle purge and the inter-cycle purge.

In some embodiments, the reaction chamber is not purged between the precursor pulse and the plasma pulse. Nevertheless, in some embodiments, the precursor pulse and the plasma pulse can be separated by an intra-cycle purge. Note that, in this case, the intra-cycle purge is kept sufficiently short such as not to dilute the precursor concentration in the reaction chamber to an appreciable extent. In other words, the duration of the purge steps and the flow rate of purge gas can be selected to be sufficiently low as to ensure that not all precursor has been removed from the reaction chamber after the purge step has finished. In other words, the duration of the purge steps and purge gas flow rates used therein can be sufficiently low such that the entire reaction chamber is not evacuated during a purge step. In some embodiments, the co-reactant can be used as a purge gas.

In some embodiments, the duration of the precursor pulse, i.e. the precursor feed time, can be from at least 0.25 seconds to at most 20.0 seconds, or from at least 0.5 seconds to at most 10.0 seconds, or from at least 1.0 seconds to at most 5 seconds. In some embodiments, the precursor pulse time can be great than 0.25 seconds, or greater than 0.5 seconds, or greater than 1 second, or great than 5 seconds, or great than 20 seconds, or greater than 30 seconds, or greater than 60 seconds, or greater than 120 seconds, or greater than 360, or between 0.25 and 360 seconds. In some embodiments, the methods of the present disclosure may employ continuous plasma enhanced chemical vapor deposition (PECVD) processes, and in such embodiments, the precursor pulse time (i.e., the feed time of the precursor into the reaction chamber) can have a duration sufficient to reach the desired target thickness of the material being formed. In such embodiments, the precursor pulse time can further depend on one or more other process parameters, such as, for example, the pressure in the reaction chamber, and the RF power applied in forming the plasma.

In some embodiments, the RF on time, i.e. the duration of a plasma pulse, that is the time during which RF power is provided during a plasma pulse, can be from at least 0.25 seconds to at most 20.0 seconds, or from at least 0.5 seconds to at most 10.0 seconds, or from at least 1.0 seconds to at most 5 seconds. In some embodiments, the plasma pulse time (i.e., RF power on duration) can be great than 0.25 seconds, or greater than 0.5 seconds, or greater than 1 second, or great than 5 seconds, or great than 20 seconds, or greater than 30 seconds, or greater than 60 seconds, or greater than 120 seconds, or greater than 360, or between 0.25 and 360 seconds. In some embodiments, the methods of the present disclosure may employ continuous chemical vapor deposition (CVD) processes, and in such embodiments, the plasma pulse time (i.e., RF power on duration) can have a duration sufficient to reach the desired target thickness of the material being formed. In such embodiments, the plasma pulse time can further depend on one or more other process parameters, such as, for example, the pressure in the reaction chamber, and the RF power applied in forming the plasma.

In some embodiments, the inter-cycle purge can have a duration from at least 0.1 s to at most 2.0 s, or from at least 0.1 to at most 1.5 s for example 1.0 s.

In some embodiments, the precursor comprises a silicon precursor. In some embodiments, the precursor comprises an oxygen-free silicon precursor. In some embodiments, the precursor comprises, an oxygen-free halogenated silicon precursor. In some embodiment, the oxygen-free halogenated silicon precursor can be selected from the group consisting of halosilanes of formula SiₙH₂ₙ+₂₋ₘXₘ, wherein X is a halogen, n is from at least 1 to at most 4, and m is from at least 1 to at most 2n+2. In some embodiments, the halogen can be selected from F, Cl, Br, and I. In some embodiments, the halosilane is selected from the group consisting of Si₂Cl₆, SiCl₂H₂, SiCl₅H, SiCl₄, SiHCl3, Si₃H₈, Si₂Cl₃H₃, SiI₂H₂, SiI₄, SiI₃H, and Si₂₁₄H₂.

In some embodiments, a precursor utilized in the embodiments of the present disclosure can have a chemical formula which does not contain oxygen atoms (O), nitrogen atoms (N), and carbon atoms (C). In some embodiments, a precursor employed in the formation of the gap-filling fluids of the present disclosure, can be oxygen free, and nitrogen free, and carbon free. In particular embodiments, a precursor employed in the formation of the gap-filling fluids of the present disclosure can be oxygen free. It should be noted that although a suitable precursor has a chemical formula which does not contain oxygen atoms (O), said precursor may still contain trace amounts of oxygen due to oxygen contamination from external sources, e.g., due to the precursor manufacturing/storage process, and/or oxygen contamination from source vessels, gas lines, etc. In some embodiments, the precursor comprises a halosilane having a chemical formula which does not contain oxygen atoms (O), nitrogen atoms (N), and carbon atoms (C). In some embodiments, the precursor can comprise two or more halosilanes having a chemical formula which does not contain oxygen atoms (O), nitrogen atoms (N), and carbon atoms (C).

In some embodiments, the co-reactant can comprise an oxygen-free co-reactant. In some embodiments, the co-reactant(s) utilized in the embodiments of the present disclosure can have chemical formulae which do not contain oxygen atoms (O), nitrogen atoms (N), and carbon atoms (C). In some embodiments, co-reactant(s) employed in the formation of the gap-filling fluids of the present disclosure, can be oxygen free, and nitrogen free, and carbon free. In particular embodiments, the co-reactant(s) employed in the formation of the gap-filling fluids of the present disclosure are oxygen free. It should be noted that although suitable co-reactants can have chemical formulae which do not contain oxygen atoms (O), such co-reactants may still contain an amount of unwanted trace oxygen due to oxygen contamination from external sources, e.g., due to the co-reactant manufacturing/storage processes, or oxygen contamination from source vessels, gas lines, etc.

In some embodiment, the co-reactant can comprise a noble gas or multiple noble gases. Suitably, the noble gas can be selected from the group consisting of helium (He), neon (Ne), argon (Ar), and krypton (Kr). In some embodiments, the noble gas essentially consists of Ar. In some embodiments, the co-reactant can comprise the noble gas and hydrogen (H₂.). It shall be understood that when a noble gas such as argon is used as a reactant, the noble gas is not substantially incorporated in the gap-filling fluid. This notwithstanding, when the co-reactant comprises H₂, hydrogen comprised in the co-reactant may be incorporated in the gap-filling fluid.

In some embodiments, all of the gases supplied to the reaction chamber which are employed in the methods of the present disclosure for filling a gap feature are the precursor, the co-reactant, an optional carrier such as Ar, and/or He, and an optional plasma ignition gas which can be or can include Ar, He, and/or H₂. In other words, no other gases are provided to the reaction chamber than those listed, in these embodiments. In some embodiments, the carrier gas and/or the plasma ignition gas can function as a reactant.

In some embodiments, providing a precursor pulse to the reaction chamber can comprise, providing an oxygen-free silicon precursor (e.g., a halosilane) to the reaction chamber by means of a carrier gas comprising a noble gas, and generating the plasma pulse can comprise, generating a plasma within the reaction chamber. In some embodiments, no gas flows in or out of the reaction chamber occurs during the duration of the plasma pulse. It should be understood that in such embodiments, the precursor pulse and the plasma pulse are not separated by a purge. Thus, in some embodiments, the co-reactant can be a carrier gas. It should be understood that a carrier gas refers to a gas that carries, or entrains, a precursor to the reaction chamber. An exemplary carrier gas includes a noble gas, such as, argon, for example.

In some embodiment, exemplary carrier gas flow rates can be of at least 0.1 slm to at most 10 slm, or of at least 0.1 slm to at most 0.2 slm, or of at least 0.2 slm to at most 0.5 slm, or of at least 0.5 slm to at most 1.0 slm, or of at least 1.0 slm to at most 2.0 slm, or of at least 2.0 slm to at most 5.0 slm, or of at least 5.0 slm to at most 10.0 slm, or of at least 0.1 slm to at most 2 slm. These exemplary carrier gas flow rates are provided for the case when the substrate is a 300 mm wafer. Flow rates for other wafer sizes can be trivially derived from these flow rates.

In some embodiments, generating the plasma pulses can comprise, generating an RF plasma within the reaction chamber. In some embodiments, a plasma power of at least 10 W to at most 500 W can be used during the generation of the plasma pulses. In some embodiments, a plasma power of at least 20 W to at most 150 W can be used during the generation of the plasma pulses. In some embodiments, a plasma power of at least 30 W to at most 100 W can be used during the generation of the plasma pulses. In some embodiments, a plasma power of at least 35 W to at most 75 W can be used during the generation of the plasma pulses. In some embodiments, a plasma power of at least 40 W to at most 50 W can be used during the generation of the plasma pulses.

In some embodiments, the methods of the present disclosure can be executed in an apparatus comprising two electrodes, in-between which the substrate is positioned. The electrodes can be positioned parallel, at a pre-determined distance called an “electrode gap”. In some embodiments, the electrode gap can be at least 5 mm to at most 30 mm, at least 5 mm to at most 10 mm, or at least 10 mm to at most 20 mm, or of at least 20 mm to at most 30 mm.

In some embodiments, a plasma frequency of at least 40 kHz to at most 2.45 GHZ can be used during the plasma pulses, or a plasma frequency of at least 40 kHz to at most 80 kHz can be used during the plasma pulses, or a plasma frequency of at least 80 kHz to at most 160 kHz can be used during the plasma pulses, or a plasma frequency of at least 160 kHz to at most 320 kHz can be used during the plasma pulses, or a plasma frequency of at least 320 kHz to at most 640 kHz can be used during the plasma pulses, or a plasma frequency of at least 640 kHz to at most 1280 kHz can be used during the plasma pulses, or a plasma frequency of at least 1280 kHz to at most 2500 kHz can be used during the plasma pulses, or a plasma frequency of at least 2.5 MHz to at least 5 MHz can be used during the plasma pulses, or a plasma frequency of at least 5 MHz to at most 50 MHz can be used during the plasma pulses, or a plasma frequency of at least 5 MHz to at most 10 MHz can be used during the plasma pulses, or a plasma frequency of at least 10 MHz to at most 20 MHz can be used during the plasma pulses, or a plasma frequency of at least 20 MHz to at most 30 MHz can be used during the plasma pulses, or a plasma frequency of at least 30 MHz to at most 40 MHz can be used during the plasma pulses, or a plasma frequency of at least 40 MHz to at most 50 MHz can be used during the plasma pulses, or a plasma frequency of at least 50 MHz to at most 100 MHz can be used during the plasma pulses, or a plasma frequency of at least 100 MHz to at most 200 MHz can be used during the plasma pulses, or a plasma frequency of at least 200 MHz to at most 500 MHz can be used during the plasma pulses, or a plasma frequency of at least 500 MHz to at most 1000 MHz can be used during the plasma pulses, or a plasma frequency of at least 1 GHz to at most 2.45 GHz can be used during the plasma pulses. In exemplary embodiments, the plasma can be an RF plasma, and RF power can be provided at a frequency of 13.56 MHz.

In some embodiments, the methods of the present disclosure, can be executed at a temperature of at least −25° C. ° ° C. to at most 200° C. In some embodiments, the present methods can be executed at a temperature of at least −25° C. to at most 0° C. In some embodiments, the present methods can be executed at a temperature of at least 0° ° C. to at most 25° C. In some embodiments, the present methods can be executed at a temperature of at least 25° C. to at most 50° C. In some embodiments, the present methods can be executed at a temperature of at least 50° ° C. to at most 75° C. In some embodiments, the present methods can be executed at a temperature of at least 75° C. to at most 150° C. In some embodiments, the present methods can be executed at a temperature of at least 150° C. to at most 200° C. This enhances the gap-filling properties of the presently provided gap-filling fluids. In some embodiments, the reaction chamber can be at a temperature of at least 70° C. to at most 90° C.

In some embodiments, a volatile precursor can be polymerized within a certain parameter range mainly defined by the partial pressure of the precursor during a plasma strike, the wafer temperature, and the total pressure in the reaction chamber. In order to adjust the “precursor partial pressure,” an indirect process parameter (i.e., dilution gas flow) may be used to control the precursor partial pressure. The absolute value of the precursor partial pressure may not be required in order to control flowability of the deposited film, rather instead, a ratio of flow rate of precursor to flow rate of the remaining gas, and the total pressure in the reaction chamber at a reference temperature and total pressure can be used as practical control parameters.

The above notwithstanding, and in some embodiments, the reaction chamber can be maintained at a pressure of at least 600 Pa to at most 10000 Pa. For example, the pressure in the reaction chamber may be maintained at a pressure of at least 600 Pa to at most 1200 Pa, or at a pressure of at least 1200 Pa to at most 2500 Pa, or at a pressure of at least 2500 Pa to at most 5000 Pa, or at a pressure of at least 5000 Pa to at most 10000 Pa.

In some embodiments, the methods of the present disclosure, can be executed at a pressure of at least 500 Pa, or at a pressure of at least 700 Pa. In some embodiment, the present methods can be executed at a pressure of at least 900 Pa. Such pressures can enhance the gap-filling properties of the presently provided gap-filling fluids.

In some embodiments, the reaction chamber can be maintained at a pressure of at least 500 Pa to at most 1500 Pa, and the reaction chamber can be maintained at a temperature of at least 50° C. to at most 150° C. In some embodiments, the present methods can be executed at a pressure of at least 500 Pa to at most 10 000 Pa and at a temperature of at least 50° C. to at most 200° ° C. In some embodiments, the present methods can be executed at a pressure of at least 700 Pa and at a temperature of at least 50° C. to at most 150° ° C. In some embodiments, the present methods can be executed at a pressure of at least 900 Pa, and at a temperature of at least 50° ° C. to at most 75° C.

In some embodiments, not only the pressure within the reaction chamber can be controlled and maintained, but in addition the atmosphere within the reaction chamber can also be controlled and maintained. In some embodiments, the atmosphere within reaction chamber can be substantially oxygen free, in other words, the amount of free oxygen contaminants in the atmosphere within the reaction chamber can be minimized below a controlled minimum threshold value.

In some embodiments, the methods of the present disclosure are executed using an apparatus comprising, a precursor source which includes a precursor recipient, e.g. a precursor canister, a precursor bottle, or the like; and one or more gas lines operationally connecting the precursor recipient to the reaction chamber. In such embodiments, the precursor recipient may be suitably maintained at a temperature which is from at least 5° ° C. to at most 50° C. lower than the temperature of the reaction chamber, or at a temperature which is from at least 5° ° C. to at most 10° C. lower than the temperature of the reaction chamber, or at a temperature which is from at least 10° C. to at most 20° C. lower than the temperature of the reaction chamber, or at a temperature which is from at least 30° C. to at most 40° C. lower than the temperature of the reaction chamber, or at a temperature which is from at least 40° C. to at most 50° C. lower than the temperature of the reaction chamber.

In some embodiment, the gas lines may be suitably maintained at a temperature between the temperature of the precursor recipient and the reaction chamber. For example, the gas lines may be maintained at a temperature which is from at least 5° C. to at most 50° C., or from at least 5° ° C. to at most 10° C., or from at least 10° C. to at most 20° C., or from at least 30° C. to at most 40° C., or from at least 40° C. to at most 50° C. lower than the temperature of the reaction chamber. In some embodiments, at least a part of the gas lines and the reaction chamber can be maintained at a substantially identical temperature which is higher than the temperature of the precursor recipient.

In some embodiments, the substrate rests on a susceptor in the reaction chamber while the gap-filling fluid is formed, and the susceptor temperature can be from at least 10° C. to at most 150° C., or from at least 25° C. to at most 100° ° C., or from at least 50° C. to at most 75° C.

Flowable films may be temporarily obtained when a volatile precursor is polymerized/oligomerized by a plasma and deposited on a surface of a substrate, wherein a gaseous precursor (e.g. a monomer) is activated or fragmented by energy provided by plasma gas discharge so as to initiate polymerization, and when the resultant material is deposited on the surface of the substrate, the material shows temporarily flowable behavior. In accordance with exemplary embodiments, when the deposition step is complete, the flowable film is no longer flowable but is solidified, and thus, a separate solidification process is not required. In other embodiments, the flowable film can be densified and/or solidified after deposition. Densifying and/or solidifying the flowable film can be done by means of a curing step (also called “cure”).

Accordingly, in some embodiments, the methods of the present disclosure can include steps of curing the gap-filling fluid. These curing steps can increase the thermal resistance of the gap-filling fluid. In other words, the curing steps can increase the resistance of the gap-filling fluid against deformation and/or mass loss at elevated temperatures. Further details regarding curing methods for gap-filling fluids are described in U.S. Patent Publication No. US 20220223411 (herein after referred to as the 3411 reference), the entire contents of which are incorporated by reference herein in their entirety and for all purposes.

The embodiments of the present disclosure further comprise apparatus for performing the exemplary methods described herein. The apparatus of the present disclosure can comprise, a reaction chamber, a radio frequency power source, a gas injection system, a precursor gas source, a co-reactant gas source, an exhaust, and a controller. The reaction chamber comprises a substrate support and an upper electrode. The substrate support comprises a lower electrode. The radio frequency power source is arranged for generating a radio frequency power waveform. The gas injection system is in fluid connection with the reaction chamber. The precursor gas source is arranged for introducing a silicon precursor into the reaction chamber. Optionally, the silicon precursor is introduced in the reaction chamber by means of a carrier gas. The co-reactant gas source is arranged for introducing a co-reactant in the reaction chamber. The exhaust is suitably arranged for removing reaction products and unused reactants from the reaction chamber. The controller is programmed or otherwise configured to cause the methods described elsewhere herein to be conducted. The controller(s) communicate with the various power sources, heating systems, pumps, robotics, and gas flow controllers or valves of the system, as will be appreciated by the skilled artisan.

In some embodiments, the precursor source that comprises a precursor recipient, e.g. a precursor canister, a precursor bottle, or the like; and one or more gas lines operationally connecting the precursor recipient to the reaction chamber. In such embodiments, the precursor recipient may be suitably maintained at a temperature which is from at least 5° C. to at most 50° C. lower than the temperature of the reaction chamber, or at a temperature which is from at least 5° C. to at most 10° C. lower than the temperature of the reaction chamber, or at a temperature which is from at least 10° ° C. to at most 20° C. lower than the temperature of the reaction chamber, or at a temperature which is from at least 30° C. to at most 40° C. lower than the temperature of the reaction chamber, or at a temperature which is from at least 40° C. to at most 50° C. lower than the temperature of the reaction chamber. The gas lines may be suitably maintained at a temperature between the temperature of the precursor recipient and the reaction chamber. For example, the gas lines may be maintained at a temperature which is from at least 5° C. to at most 50° C., or from at least 5° ° C. to at most 10° C., or from at least 10° C. to at most 20° C., or from at least 30° C. to at most 40° C., or from at least 40° C. to at most 50° C. lower than the temperature of the reaction chamber. In some embodiments, the gas lines and the reaction chamber are maintained at a substantially identical temperature which is higher than the temperature of the precursor recipient.

In some embodiments, the gas injection system comprises a precursor delivery system that employs a carrier gas for carrying the precursor to one or more reaction chambers. In some embodiments, continuous flow of carrier gas can be accomplished using a flow-pass system. In the flow-pass system, a carrier gas line is provided with a detour line having a precursor reservoir (bottle), and the main line and the detour line are switched, wherein when only a carrier gas is intended to be fed to a reaction chamber, the detour line is closed, whereas when both the carrier gas and the precursor gas are intended to be fed to the reaction chamber, the main line is closed and the carrier gas flows through the detour line and flows out from the bottle together with the precursor gas. In this way, the carrier gas can continuously flow into the reaction chamber and can carry the precursor gas in pulses by switching the main line and the detour line.

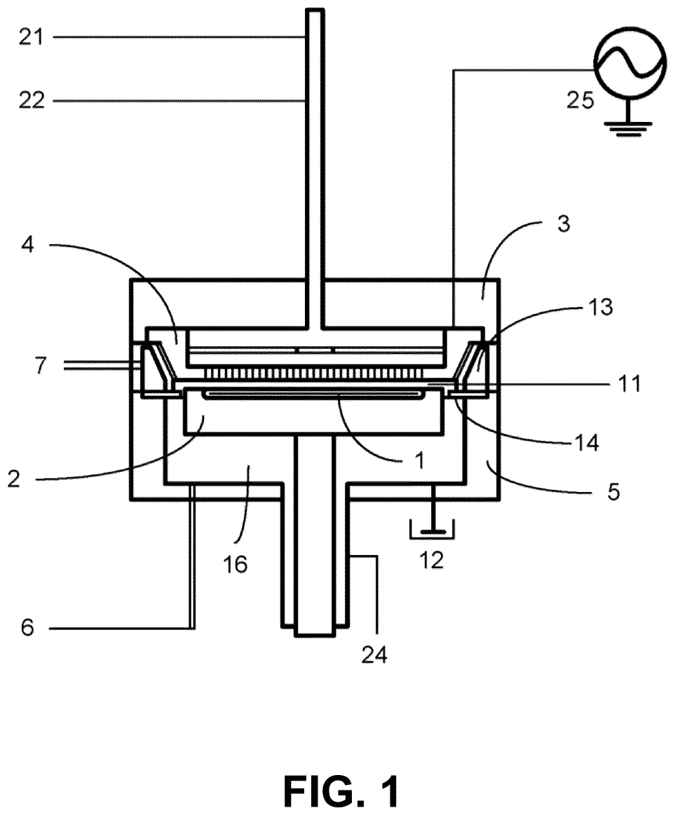

The methods of the present disclosure may be executed in any suitable apparatus, including in a reactor as shown in FIG. 1. Similarly, the presently provided structures may be manufactured in any suitable apparatus, including a reactor as shown in FIG. 1. FIG. 1 is a schematic view of a plasma-enhanced atomic layer deposition (PEALD) apparatus, desirably in conjunction with controls programmed to conduct the processes described below, usable in some embodiments of the present invention. In this figure, by providing a pair of electrically conductive flat-plate electrodes (2,4) in parallel and facing each other in the interior (11) (reaction zone) of a reaction chamber (3), applying RF power (e.g. at 13.56 MHz and/or 27 MHz) from a power source (25) to one side, and electrically grounding the other side (12), a plasma is excited between the electrodes. A temperature regulator may be provided in a lower stage (2), i.e. the lower electrode. A substrate (1) is placed thereon and its temperature is kept constant at a given temperature. The upper electrode (4) can serve as a shower plate as well, and a co-reactant gas and/or a dilution gas, if any, as well as a precursor gas can be introduced into the reaction chamber (3) through a gas line (21) and a gas line (22), respectively, and through the shower plate (4). Additionally, in the reaction chamber (3), a circular duct (13) with an exhaust line (17) is provided, through which the gas in the interior (11) of the reaction chamber (3) is exhausted. Additionally, a transfer chamber (5) is disposed below the reaction chamber (3) and is provided with a gas seal line (24) to introduce seal gas into the interior (11) of the reaction chamber (3) via the interior (16) of the transfer chamber (5) wherein a separation plate (14) for separating the reaction zone and the transfer zone is provided. Note that a gate valve through which a wafer may be transferred into or from the transfer chamber (5) is omitted from this figure. The transfer chamber is also provided with an exhaust line (6).

A skilled artisan will appreciate that the apparatus includes one or more controller(s) (not shown) programmed or otherwise configured to cause the deposition process described elsewhere herein to be conducted. The controller(s) communicate with the various power sources, heating systems, pumps, robotics and gas flow controllers or valves of the reactor, as will be appreciated by the skilled artisan. The controller(s) include electronic circuitry including a processor, and software to selectively operate valves, manifolds, heaters, pumps and other components included in the system. Such circuitry and components operate to introduce precursors, reactants, and optionally purge gases from the respective sources (e.g., bottle 20). The controller can control timing of gas supply sequences, temperature of the substrate and/or reaction chamber (3), pressure within the reaction chamber (3), and various other operations to provide proper operation of the system. The controller(s) can include control software to electrically or pneumatically control valves to control flow of precursors, reactants and purge gases into and out of the reaction chamber (3). Controller(s) can include modules such as a software or hardware component, e.g., a FPGA or ASIC, which performs certain tasks. It shall be understood that where the controller includes a software component to perform a certain task, the controller is programmed to perform that particular task. A module can advantageously be configured to reside on the addressable storage medium, i.e. memory, of the control system and be configured to execute one or more processes.

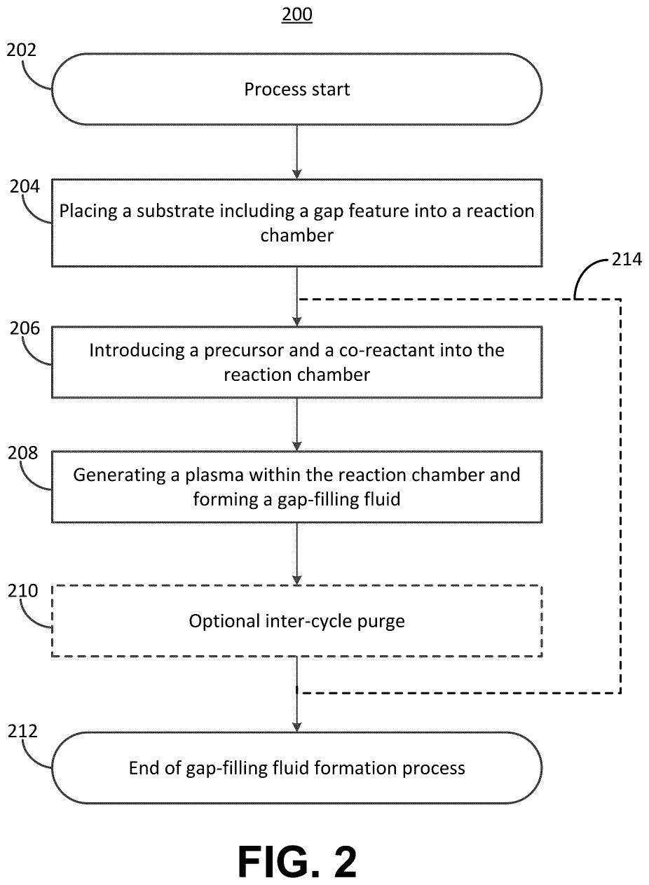

As further example of the methods of the present disclosure, FIG. 2 illustrates a process flow diagram which demonstrates an exemplary method 200 for forming a gap-filling fluid within a gap feature in and/or on a substrate.

In more detail, the exemplary method 200 can commence with the process start step (step 202), and may continue with the process step 204 which comprises, placing a substrate including a gap feature into a reaction chamber, wherein the atmosphere within the reaction chamber is substantially oxygen free. In addition, the exemplary methods can utilize oxygen-free-precursor(s) and oxygen-free co-reactant(s).

In some embodiments, the reaction chamber may comprise a component (or sub-system) of a plasma deposition apparatus, such as, but not limited to, a plasma enhanced chemical vapor deposition (PECVD) apparatus, or a plasma enhanced atomic layer deposition (PEALD) apparatus. In some embodiments of the disclosure, the gap-filling fluids of the present disclosure maybe deposited employing a plasma enhanced chemical vapor deposition process operating in a “pure” plasma enhanced CVD mode (i.e., without using temporal deposition methods involving, for example, alternating, time varying, precursor pulses, co-reactant pulses, and RF plasma pulses). In such embodiments, an oxygen-silicon precursor, oxygen-free co-reactant(s), and RF power may all be applied concurrently, or at least for an overlapping time period, i.e., there can be a substantial temporal overlap between introducing the precursor, the co-reactants(s), and applying RF power to generate a plasma within the reaction chamber.

In additional embodiments, process step 204 (FIG. 2) can further include, providing a reaction chamber which is substantially free of oxygen. In other words, the method 200 may comprise, maintaining the atmosphere within the reaction chamber in an oxygen free state. For example, the minimization of oxygen and/or oxygen containing contaminants from within the reaction chamber can prevent unwanted and/or premature oxidation of a silicon gap-filling fluid formed therein. Process step 204 can further include heating the substrate to a desired deposition temperature whilst maintaining a controlled pressure within the reaction chamber, as previously described herein.

The exemplary method 200 (FIG. 2) may continue with a process step 206 which comprises, introducing a precursor into the reaction, and introducing a co-reactant into the reaction chamber. The precursor may comprise a oxygen-free halosilane, such as, hexachlorosilane (Si₂Cl₆), for example. In addition, the oxygen-free co-reactant may comprise one or more noble gases, such as, for example, helium (He), and argon (Ar). The co-reactant(s) may also be introduced into the reaction chamber with an addition carrier gas, such as, hydrogen (H₂), for example.

In some embodiments, process step 206 may comprise, introducing a precursor and a co-reactant into the reaction chamber, wherein the precursor and the co-reactant have chemical formulae which do not contain oxygen atoms (O), nitrogen atoms (N), and carbon atoms (C).

The method 200 may continue with a process step 208 which comprises, generating a plasma within the reaction chamber, whereby the oxygen-free precursor and the oxygen-free co-reactant react in the presence of the plasma to a form a silicon containing gap-filling fluid that at least partially fills the gap feature. In some embodiments, the silicon containing gap-filling fluid formed during process step 208 comprises, an oxygen free gap-filling fluid that at least partially fills the gap feature. In some embodiments, the gap-filling fluid formed during process step 208 comprises, an inorganic polysilane, or an inorganic oligomeric silane. Suitable RF powers, the applied RF time period, and suitable electrode distances have been previously discussed and are therefore not repeated herein.

Optionally, the process steps 204, 206, 208, 210, can be repeated one or more times (e.g., via process cycle loop 214) until a desired amount of gap-filling fluid is formed within the gap features disposed in/on the substrate. Optionally, successive process cycles can be separated by an inter-cycle purge step (optional process step 210). When a desired amount of gap-filling fluid is formed within the gap feature, the exemplary method 200 (FIG. 2) can be terminated, as illustrated by the end process step 212.

In some embodiments of the disclosure, the gap-filling fluid may be subjected to a curing process. For example, the gap-filling fluid may be subjected to curing processes to solidify the gap-filling fluid. Further details regarding curing methods for gap-filling fluids are described in U.S. Patent Publication No. US 20220223411 the entire contents of which are incorporated by reference herein in their entirety and for all purposes and therefore not repeated herein.

In additional embodiments of the disclosure, the gap-filling fluid formed during the exemplary method 200 (FIG. 2) may be subjected to further process steps to form an oxide containing gap-filling material within the gap features. In some embodiments, the oxide containing gap-filling material may comprise a silicon oxide gap filling material. In some embodiments, the oxide containing gap-filling material may comprise a silicon dioxide gap-filling material. In some embodiments, the oxide containing gap-filling material may comprise a bulk stoichiometric silicon dioxide (SiO₂) gap filling material.

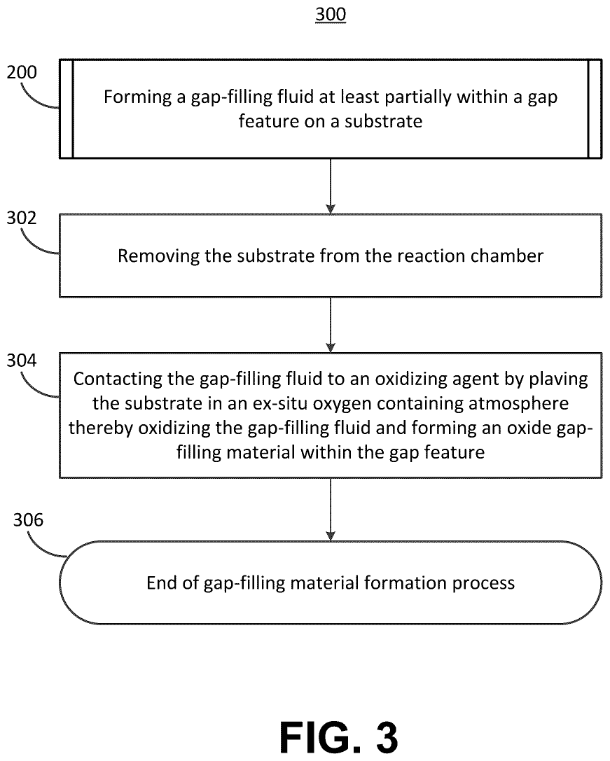

For example, FIG. 3 illustrates a process flow diagram for an exemplary method 300 which comprises, performing additional process steps on the gap-filling fluid formed within the gap features by the previously described methods, e.g., formed by the exemplary method 200 (FIG. 2).

In more detail, after forming the gap-filling fluid at least partially filling a gap feature (sub-process 200 of FIG. 3), the additional process steps of method 300 may continue by, removing the substrate with the gap-filling fluid thereon from the reaction chamber (step 302). For example, the reaction chamber may be purged of any excess precursor, co-reactants, and any reaction by-products, and the substrate may then be either manually or robotically removed from the reaction chamber. In some embodiments, wherein the reaction chamber is connected to additional deposition apparatus sub-systems, such as, for example, a load lock, a cooling station, or a curing station, the substrate may be completely removed from the deposition apparatus employed for depositing the gap-filling fluid.

Upon removal of the substrate from the reaction chamber (step 302), the method 300 may continue by, contacting the substrate with the gap-filling fluid thereon with an oxidizing agent. In some embodiments, the substrate can be removed from the reaction chamber and subsequent be placed in an ex-situ oxygen containing atmosphere. In some embodiments, the ex-situ oxygen containing atmosphere may comprise at least one of, a room temperature oxygen atmosphere, or a room temperature ambient air atmosphere. As used herein, the term “ex-situ oxygen atmosphere” refers to an atmosphere containing oxygen outside of the reaction chamber in which the gap-filling fluid is deposited. In other words, an “ex-situ oxygen atmosphere” is remote from the gap-filling fluid deposition reaction chamber.

In some embodiments, the substrate with the gap-filling fluid thereon maybe placed into an additional reaction chamber which is fed with an ex-situ source of oxygen to provide a room temperature oxygen atmosphere within the additional reaction chamber. In such embodiments, the additional chamber may be connected to the deposition apparatus employed for depositing the gap-filling fluid and the substrate with the gap-filling fluid thereon may be transferred to the additional reaction chamber under a controlled atmosphere free of oxygen.

In alternative embodiments, the substrate with the gap-filling fluid thereon may be placed in an ex-situ oxygen atmosphere comprising standard ambient air at room temperature. For example, the substrate with the gap-filling fluid thereon can be removed from the reaction chamber in which the gap-filling fluid was deposited and subsequently removed from completely from all connected components/sub-components and systems of the plasma deposition apparatus employed in deposited the gap-fill fluid such that the substrate is placed into an ambient air atmosphere at room temperature.

Once the substrate is placed in an ex-situ oxygen containing atmosphere, method 300 may continue by, forming a bulk oxide gap-filling material within the gap feature. For example, exposing the substrate with the gap-filling fluid thereon to an ex-situ oxygen containing atmosphere can oxidize the gap-filling fluid. In other words, exposing the substrate with the gap-filling fluid thereon to an ex-situ oxygen containing atmosphere can result in the formation of a oxide gap-filling material within the gap feature. In some embodiments of the disclosure, exposing the substrate with the gap-filling fluid thereon to an ex-situ oxygen containing atmosphere can further comprise, oxidizing the gap-filling fluid and in doing so forming an oxide gap-filling material within the gap feature.

In some embodiments, the gap-filling fluid may comprise a silicon containing gap-filling fluid and subsequent exposure to an ex-situ oxygen containing atmosphere can result in the oxidation of the silicon containing gap-filling fluid thereby forming a silicon oxide gap-filling material within the gap feature. In some embodiments, the gap-filling fluid may comprise an oxygen free gap-filling fluid and subsequent exposure to an ex-situ oxygen containing atmosphere can result in the oxidation of the oxygen free gap-filling fluid thereby forming a bulk oxide gap-filling material within the gap feature.

In some embodiments, a silicon oxide gap-filling material comprises a silicon dioxide gap-filling material, for example, the silicon dioxide gap-filling material may comprise a bulk silicon dioxide (SiO₂) gap-filling material with a stoichiometry substantially matching, or even matching, that of bulk stoichiometric silicon dioxide (SiO₂), as determined by x-ray photoelectron spectroscopic methods. In such embodiments, the bulk stoichiometric silicon dioxide (SiO₂) gap-filling material may partially, or completely fill, the gap-feature without the formation of voids or seams, as determined by high magnification microscopy methods, such as, for example, scanning tunnelling electron microscopy (STEM).

In some embodiments of the disclosure, the gap-filling fluid comprises an oxygen free gap-filling fluid disposed within the gap feature, which upon exposure to an ex-situ oxygen atmosphere (process step 304) can spontaneously oxidize to a bulk silicon dioxide (SiO₂) gap-filling material having a stoichiometry substantially matching, or even matching, that of a bulk stoichiometric silicon dioxide (SiO₂) gap-filling material, as determined by x-ray photoelectron spectroscopic methods. In such embodiments, the spontaneously formed bulk stoichiometric silicon dioxide gap-filling material may partially, or completely fill, the gap-feature without the formation of voids or seams, as determined by high magnification microscopy methods, such as, for example, scanning tunnelling electron microscopy (STEM).

It should be noted that the methods of the present disclosure comprise, exposing the gap-filling fluid to an ex-situ oxygen atmosphere at room temperature which results in the oxidation of the bulk of the gap-filling fluid, not just the oxidation of the exposed surfaces of the gap-filling fluid as would commonly be expected. However, the embodiments of the present disclosure are able to oxidize the bulk of the gap-filling fluid without the use of additional processes.

Upon formation of the oxide gap-filling material within the gap feature, the exemplary method 300 may conclude (step 306). Subsequently, the substrate with the partially filled, or completely filled, gap feature may be subjected to additional processes, such as, for example, post-deposition treatments and additional processes for the fabrication of semiconductor device structure, and/or semiconductor integrated circuits.

In some embodiments, methods for forming a gap-filling liquid and oxidizing said gap-filling liquid can employ a cyclical process. In some embodiments, a cyclical process can be employed which utilizes an in-situ or ex-situ oxidizing step to enable oxidation of the gap-filling fluid to form the silicon oxide gap-filling material.

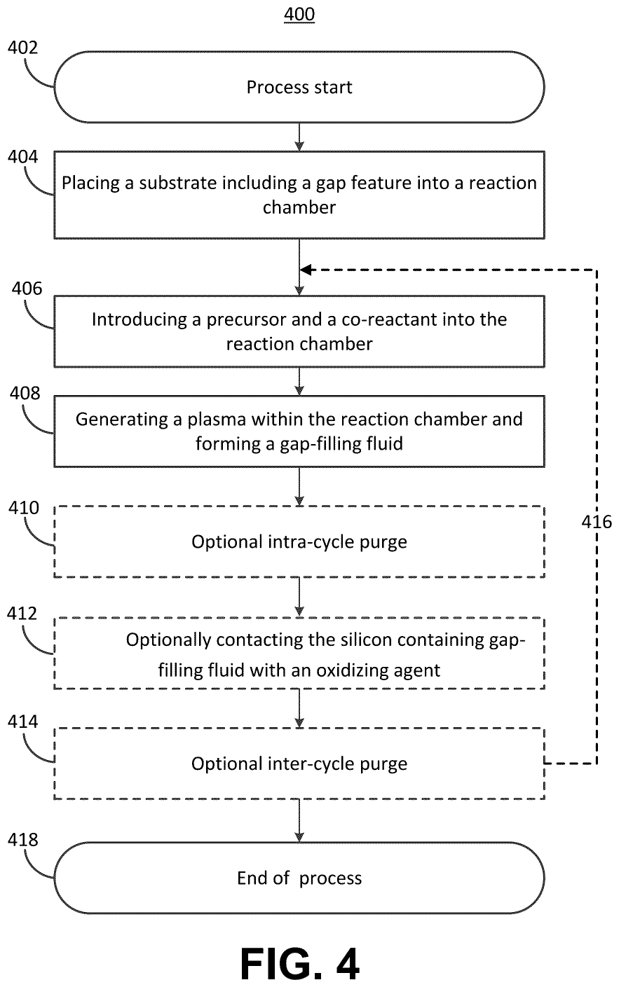

For example, FIG. 4 illustrates an exemplary cyclic process 400 for forming an silicon oxide gap-filling material. It should be noted that many of the process steps employed in the exemplary cyclical process 400 are similar, or the same, as those previously described with reference to exemplary method 200 and therefore those steps are summarized below in the interest of brevity and additional process are described in more detail. In addition, the materials formed by the exemplary cyclical process 400, and the properties of said material, are similar, or the same, as those previously described, and therefore are not repeated herein in the interest of brevity.

Therefore, in some embodiments the disclosure, the exemplary cyclical process 400 can start at step 402 and continue by place the substrate including a gap feature into a reaction chamber (step 404), as previously described in process step 204 (FIG. 2). In addition, the substrate may be heated to a desired deposition temperature and the pressure within the reaction chamber may be controlled to a desired value, as previously described herein.

The exemplary cyclical process 400 can continue with the cyclical portion of the process. Therefore, in some embodiment, forming the silicon oxide gap-filling material can further comprise, performing multiple cycles of a cyclical process in which a unit cycle comprises, introducing an oxygen-free halogenated silicon precursor and an oxygen-free co-reactant into the reaction chamber (step 406), generating a plasma within the reaction chamber (step 408), wherein the oxidizing agent is introduced into the reaction chamber in one or more of the unit cycles (step 412).

In more detail, the cyclical process can comprise introducing the precursor and the co-reactant into the reaction chamber (step 406), as previously described herein above. The process can further comprise generating a plasma within the reaction chamber thereby forming a gap-filling fluid (step 408), as previously described herein above. After the plasma pulse step (step 408) the reaction chamber can be optionally be purged of excess precursor, co-reactant, reactive species generated by the plasma, and any reaction by-products (step 410).

Upon optionally purging the reaction chamber, the exemplary cyclical process 400 can include a subsequent process step 412 which comprising, contacting the silicon containing gap-filling fluid with an oxidizing agent. For example, the oxidizing agent can comprise at least one of molecular oxygen (O₂), ozone (O₃), nitrogen monoxide (NO), nitrous oxide (N₂O), nitrogen dioxide (NO₂), or carbon dioxide (CO₂). In some embodiments, the oxidizing agent can contact with gap-filling fluid in-situ, i.e., the oxidizing agent can be introduced into the reaction chamber in which the silicon containing gap-filling fluid was formed. In some embodiments, the oxidizing agent can contact the substrate and particularly the gap-filling fluid for sufficient time so as to form a silicon oxide gap-filling material. In alternative embodiments, the oxidizing agent can contact the gap-filling fluid ex-situ, i.e., external to the reaction chamber utilized to form the gap-filling fluid.

In some embodiments, the exemplary cyclical 400 can be performed on a cluster type tool including multiple reaction chambers, and/or multiple process modules including two (2) or more reaction chambers, such as, for example, dual chamber modules (DCM), or a quad chamber modules (QCM). In such embodiments, the silicon containing gap-filling fluid may be formed in a first reaction chamber, and the oxidation of the silicon containing gap-filling fluid by an oxidizing agent may be performed in a second reaction chamber, with the substrate being transported back and forth between the first chamber and the second chamber under a controlled environment (i.e., controlled temperature, pressure, and atmosphere). In such embodiments, a third reaction chamber can also be employed wherein post-deposition processes can be performed on the deposited silicon oxide gap-filling material, wherein again the transport between the first, second, and third reaction chamber is performed under a controlled environment. In such embodiments, the temperature within the first, second, and third reaction chamber can be different or be maintained at the same temperature within all the reaction chamber utilized. In some embodiments, the temperature within the second reaction chamber employed in the oxidation of the gap-filling fluid may be maintained at approximately room temperature or above.

In further embodiments of the disclosure, the first, second, and the third reaction chambers can be disposed within a single common process module. In alternative embodiments, the first, second, and third reaction chambers may be disposed in different, connected process modules, the multiple process modules forming at least part of a common cluster processing tool. As a non-limiting example, a cluster tool can comprise at least two process modules (e.g., DCMs and/or QCMs), wherein a first process module includes a reaction chamber configured for forming the silicon containing gap-filling fluid, and a second process module includes a further reaction chamber configured for the oxidation of the silicon containing gap-filling fluid, wherein the substrate is cycled back forth between the first and second process modules (and associated reaction chambers) as part of cyclical deposition-oxidation process. In such embodiments, an additional reaction chamber can be employed to perform post deposition process on the silicon oxide gap-filling material, wherein the additional post deposition reaction chamber can be disposed in a third process module (e.g., a DCM or QCM), or alternatively the post deposition reaction chamber may be disposed within the first or second process module.

With continued reference to FIG. 4 and exemplary cyclical process 400, after the oxidizing step (step 412), the reaction chamber can optionally be purged of any excess oxidizing agent and/or reaction by-products (step 414). The cyclical process 400 can then optionally continue, via process cycle loop 416, and a further unit cycle can be performed wherein the substrate again under goes the steps of forming a silicon containing gap-filling fluid (steps 406 and 408) and subsequently oxidizing said gap-filling fluid (step 412) to forming a silicon oxide gap-filling material.

In some embodiments, the exemplary cyclical process 400 can employ process step 414 (i.e., the oxidizing step) in each unit cycle.

In alternative embodiments, the oxidizing step 412 may optionally be omitted in particular unit cycles. For example, the exemplary cyclical process 400 may perform the oxidizing step (step 412) every second cycle, or every third cycle, or every fifth cycle, or every tenth example, and so on. In other words, multiple cycles can be performed to form a silicon containing gap-filling fluid with increasing thickness without an oxidation step, and after a desired thickness of the silicon containing gap-filling fluid is achieved, a cycle can be performed that includes the oxidation step (step 412). In some embodiments, the exemplar cyclical process 400 (FIG. 4) may be repeated, 10 times, or 20 times, or 50 times, or 100 times, or 250 times, or 500 times, or more than 1000 times, wherein the optional oxidizing step (step 412) is included in at least one cycle. In some embodiments, the optional oxidizing step (412) may be performed during the final cycle prior to ending the process at step 418. In some embodiments, the exemplary cyclical process 400 is terminated (step 418) upon achieving a desired thickness of the silicon oxide gap-filling material within a gap feature.

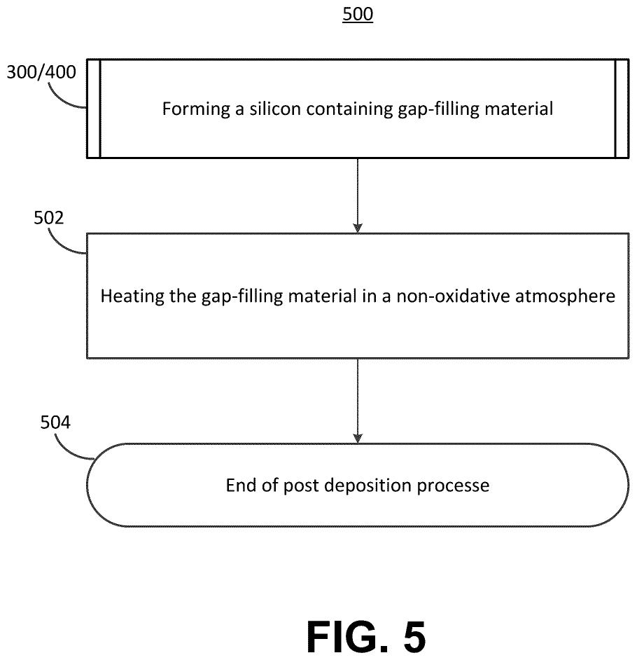

In some embodiments of the disclosure, upon formation of the silicon oxide gap-filling material within one or more gap features, the as-deposited silicon oxide gap-filling material may be subjected to one or more post deposition processes. For example, FIG. 5 illustrates an exemplary process 500 which comprises, forming a silicon oxide gap-filling material employing the methods described herein above (e.g., processes 300 and 400) and subsequently treating the silicon oxide gap-filling material to a post-deposition process (step 502) which comprises, thermally annealing the silicon oxide gap-filling material in a non-oxidative atmosphere.

In some embodiments, the post-deposition process (step 502) can include, heating the silicon oxide gap-filling material in a nonoxidative atmosphere to a temperature between 200° C. and 110° ° C. thereby increasing the density of the silicon oxide gap-filling material and/or reducing the wet etch rate ratio (WERR) of the silicon oxide gap-filling material. In some embodiments, the post deposition thermal annealing process performed on the silicon oxide gap-filling material comprises, heating the silicon oxide gap-filling material to a temperature between 200° ° C. and 1100° C. in a nonoxidative atmosphere comprising argon (Ar), helium (He), hydrogen (H₂), nitrogen (N₂), or combination thereof.

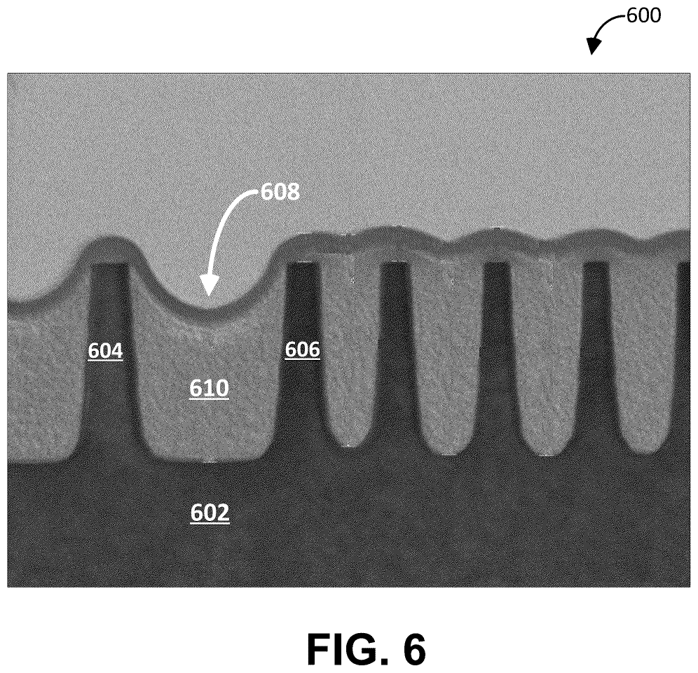

To further demonstrate the methods of the current disclosure as well as the related semiconductor structures formed by such methods, FIG. 6 shows a high magnification scanning tunneling electron microscopy (STEM) cross-sectional image of a semiconductor structure including multiple gap features that are at least partially filled with a silicon dioxide gap-filling material formed according to the embodiments of the present disclosure.

In more detail, FIG. 6 shows an exemplary structure 600 which includes a silicon substrate 602, as well as number of vertical features (two exemplary adjacent vertical features are labelled as vertical features 604 and 606). Disposed between the vertical features are a number of gap features, such as, exemplary gap feature 608 as illustrate in FIG. 4. Examination of structure 600 shows that a silicon dioxide gap-filling material 610 is formed within the gap feature 608 in accordance with the embodiments of the present disclosure.

In some embodiments, a thermally annealed silicon oxide gap-filling material formed by the methods disclosure herein (i.e., a silicon oxide gap-filling having undergone a post deposition process, such as, that of process step 502 of FIG. 5), may comprise a bulk stoichiometric silicon dioxide (SiO₂) gap-filling material which has an average refractive index greater than 1.40, or greater 1.41, or greater 1.42, or greater 1.43, or greater 1.44, or greater than 1.45, or greater 1.46, or even between 1.40 and 1.46.

In some embodiments, the as-deposited (i.e., without undergoing post deposition annealing processes) silicon oxide gap-filling material 410 may comprise, a bulk stoichiometric silicon dioxide (SiO₂) gap-filling material which has a wet etch rate ratio (WERR) at room temperature in hydrofluoric acid (0.5% concentration) less than 100 nanometers (nm) per minute, or less than 75 nm per minute, or less than 50 nm per minute, or less than 25 nm per minute. In some embodiments, a thermally annealed silicon oxide gap-filling material (i.e., a silicon oxide gap-filling having undergone a post deposition process, such as, that of process step 502 of FIG. 5) has a wet etch rate ratio (WERR) at room temperature in hydrofluoric acid (0.5% concentration) less than 30 nanometers (nm) per minute, or less than 20 nm per minute, or less than 15 nm per minute, or less than 12 nm per minute

Although certain embodiments and examples have been discussed, it will be understood by those skilled in the art that the scope of the claims extend beyond the specifically disclosed embodiments to other alternative embodiments and/or uses and obvious modifications and equivalents thereof. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

In the present disclosure, where conditions and/or structures are not specified, the skilled artisan in the art can readily provide such conditions and/or structures in view of the present disclosure, as a matter of routine experimentation.

What is claimed is:

1. A method for forming a gap-filling material within a gap feature, the method comprising:
placing a substrate including a gap feature into a reaction chamber;
introducing an oxygen-free halogenated silicon precursor into the reaction chamber;
introducing an oxygen-free co-reactant comprising a noble gas into the reaction chamber;
generating a plasma within the reaction chamber, whereby the oxygen-free halogenated silicon precursor and the oxygen-free co-reactant react in the presence of the plasma to form a silicon containing gap-filing fluid that at least partially fills the gap feature; and
contacting the substrate with the silicon containing gap-filling fluid thereon with an oxidizing agent, thereby oxidizing the silicon containing gap-filling fluid and in doing so forming a silicon oxide gap-filling material within the gap feature.

2. The method of claim 1, wherein the oxygen-free halogenated silicon precursor is selected from the group consisting of halosilanes of formula SiₙH₂ₙ+₂₋ₘXₘ, wherein X is a halogen, n is from at least 1 to at most 4, and m is from at least 1 to at most 2n+2.

3. The method of claim 2, wherein the halosilane is selected from the group consisting of Si₂Cl₆, SiCl₂H₂, SiCl₅H, SiCl₄, SiHCl3, Si₃H₈, Si₂Cl₃H₃, SiI₂H₂, SiI₄, SiI₃H, and Si₂₁₄H₂.

4. The method of claim 1, further comprising, heating the silicon oxide gap-filling material in a nonoxidative atmosphere to a temperature between 200° C. and 1100° C. thereby increasing the density of the silicon oxide gap-filling material and reducing the wet etch rate ratio of the silicon oxide gap-filling material.

5. The method of claim 1, wherein the silicon oxide gap-filling material comprises a silicon dioxide gap-filling material.

6. The method of claim 5, wherein the silicon dioxide gap-filling material comprises a bulk stoichiometric silicon dioxide (SiO₂) gap-filling material as determined by x-ray photoelectron spectroscopy.

7. The method of claim 1, wherein forming the gap-filling material further comprises, performing multiple cycles of a cyclical process in which a unit cycle comprises:
introducing the oxygen-free halogenated silicon precursor and the oxygen-free co-reactant into the reaction chamber;
generating the plasma within the reaction chamber; and
wherein the oxidizing agent is introduced into the reaction chamber in one or more of the unit cycles.

8. The method of claim 1, wherein forming a gap-filling material further comprises, removing the substrate from the reaction chamber, and subsequently contacting the substrate with the oxidizing agent by placing the substrate in an ex-situ oxygen containing atmosphere.

9. A semiconductor structure including a silicon dioxide gap-filling material formed by claim 1.

10. An apparatus configured and arranged for performing the method of claim 1.

11. A method for at least partially filing a gap feature with a gap-filling material, the method comprising:
placing a substrate including a gap feature into a reaction chamber;
introducing a precursor and co-reactant into the reaction chamber, wherein the precursor and the co-reactant have chemical formulae which do contain oxygen (O), nitrogen (N), and carbon (C),
generating a plasma within the reaction chamber, whereby the precursor and the co-reactant react in the presence of the plasma to form an oxygen-free gap-filling fluid that at least partially fills the gap feature; and
exposing the substrate with the oxygen-free gap-filling fluid thereon to an oxidizing agent thereby oxidizing the oxygen-free gap-filling fluid and in doing so forming a bulk oxide gap-filling material within the gap feature.

12. The method of claim 11, wherein the precursor is selected from the group consisting of halosilanes of formula SiₙH₂ₙ+₂₋ₘXₘ, wherein X is a halogen, n is from at least 1 to at most 4, and m is from at least 1 to at most 2n+2.

13. The method of claim 11, wherein forming the gap-filling material further comprises, performing multiple cycles of a cyclical process in which a unit cycle comprises:
introducing the precursor and co-reactant into the reaction chamber;
generating the plasma within the reaction chamber; and
wherein the oxidizing agent is introduced into the reaction chamber in one or more of the unit cycles.

14. The method of claim 11, wherein forming a gap-filling material further comprises, removing the substrate from the reaction chamber, and subsequently contacting the substrate with the oxidizing agent by placing the substrate in an ex-situ oxygen containing atmosphere comprising at least one of, a room temperature oxygen atmosphere, or a room temperature ambient air atmosphere.

15. The method of claim 11, wherein the bulk oxide gap-filling material comprises a bulk stoichiometric silicon dioxide (SiO₂) gap-filling material as determined by x-ray photoelectron spectroscopy.

16. The method of claim 11, wherein the oxygen-free gap-filling fluid comprises an inorganic polysilane.

17. The method of claim 11, further comprising, performing a post-deposition thermal annealing process on a silicon oxide gap-filling material, the annealing process comprising, heating the silicon oxide gap-filling material to a temperature between 200° C. and 1100° C. in a nonoxidative atmosphere comprising argon (Ar), helium (He), hydrogen (H₂), nitrogen (N₂), or combinations thereof.

18. The method of claim 17, wherein the silicon oxide gap-filling material has a post thermal anneal average refractive index greater than 1.44 and a wet etch rate ratio less than 12.

19. A semiconductor structure including a bulk stoichiometric silicon dioxide (SiO₂) gap-filling material at least partially filling a gap feature formed according to claim 11.

20. An apparatus comprising:
a reaction chamber, the reaction chamber comprising a substrate support and an upper electrode, the substrate supports comprising a lower electrode,
a radio frequency power source arranged for generating a radio frequency power waveform;
a gas injection system fluidly coupled to the reaction chamber;
a precursor gas source for introducing a halosilane precursor and optionally a carrier gas into the reaction chamber;
a co-reactant source for introducing a co-reactant into the reaction chamber;
an exhaust; and
a controller being configured and arranged to cause the gas injection system to carrier out a method according to claim 11.
